(19) United States
(12) Patent Application Publication
(10) Pub. No.: US 2009/0238985 A1
(43) Pub. Date: Sep. 24, 2009

(54) SYSTEMS AND METHODS FOR DEPOSITION

(76) Inventor: Hugh D. Chau, San Jose, CA (US)

Correspondence Address: IPSG, P.C., P.O. BOX 700640, SAN JOSE, CA, 95170, US

(21) Appl. No.: 12/054,314

(22) Filed: Mar. 24, 2008

(51) Int. Cl. C23C 16/00

(52) U.S. Cl. 427/457; 118/728

(57) ABSTRACT

A substrate stage system for supporting and cooling a substrate during a deposition process that involves utilizing a target material is disclosed. The substrate stage system may include a substrate seat made of a thermally conductive material. The substrate stage system may also include a sealing unit coupled with the substrate seat. The sealing unit may define a boundary of a space between the substrate and the substrate seat. The substrate seat may include a gas channel for delivering a gas to the space. The sealing unit may seal the space to inhibit the gas from escaping from the space. The substrate seat may receive heat from the substrate through the gas and may dissipate the heat.

### BACKGROUND OF THE INVENTION

Deposition systems, such as sputtering deposition systems, are employed in various industries for depositing thin films of various materials on substrates (e.g., wafers). The industries may include, for example, semiconductor, magnetic storage, optical system, and micro-electromechanical system (MEMS) industries. The materials to be deposited may be, for example, aluminum oxide, zinc oxide, tin oxide, or titanium dioxide. As an example, a deposition system may utilize a plasma source to sputter a target material such that sputtered atoms of the target material (or molecules comprising the sputtered atoms) may attach to a surface of a wafer.

Wafer arrangement may be an important consideration in deposition processes and deposition system design. Conventionally, the wafer may be disposed parallel to the target material, i.e., parallel to an imaginary plane containing the long axis of the target material, based on the assumption that the sputtered atoms would generally have travel paths that are orthogonal to both the target material and the wafer.

In an example conventional arrangement, the target material may be disposed above the wafer, such that gravity may move sputtered atoms from the target toward the wafer. However, also because of gravity, contaminants, such as flakes of the target material, also may fall onto the wafer. As a result, the yield associated with the deposition process may be undesirable.

In another example conventional arrangement, the target material may be disposed below the wafer. Under this arrangement, the movement of the sputtered atoms toward the wafer may be slowed down by gravity. As a result, the deposition rate (or efficiency) for the deposition process may be undesirable.

In another example conventional arrangement, both the target material and the wafer may be disposed perpendicular to the ground, or a level plane. Under this arrangement, because of gravity, the sputtered atoms may not approach the wafer in paths orthogonal to the deposition surface of the wafer. As a result, the deposition rate for the deposition process may be undesirable. Further, the deposited thin film may not be sufficiently homogenous.

Cooling also may be an important consideration in deposition processes and deposition system design. During a deposition process, the temperature of the wafer may substantially increase such that effective cooling may be required for the wafer. Typically, a deposition system may include a gas inlet to enable a cooling gas, such as helium, to flow in to contact the wafer for absorbing thermal energy from the wafer. The cooling gas that has absorbed thermal energy from the wafer will be heated as a result of the thermal energy transfer. The deposition system may also include a gas outlet to allow the heated cooling gas to leave the wafer. In general, a continuous flow of the cooling gas may be utilized to continuously remove thermal energy from the wafer. Under this conventional arrangement, a significant amount of the cooling gas may be required (and consumed), and therefore substantial cost associated with cooling may be incurred.

### SUMMARY OF INVENTION

An embodiment of the invention relates to a substrate stage system for supporting and cooling a substrate during a deposition process that involves utilizing a target material. The substrate stage system may include a substrate seat made of a thermally conductive material. The substrate stage system may also include a sealing unit coupled with the substrate seat. The sealing unit may define a boundary of a space between the substrate and the substrate seat. The substrate seat may include a gas channel for delivering a gas to the space. The sealing unit may seal the space to inhibit the gas from escaping from the space. The substrate seat may receive heat from the substrate through the gas and may dissipate the heat.

The above summary relates to only one of the many embodiments of the invention disclosed herein and is not intended to limit the scope of the invention, which is set forth in the claims herein. These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1A illustrates a schematic representation of a deposition system including a substrate stage system in accordance with one or more embodiments of the present invention.

FIG. 1B illustrates a schematic representation of the substrate stage system illustrated in the example of FIG. 1A and including a shutter in accordance with one or more embodiments of the present invention.

FIG. 2A illustrates a schematic representation of a deposition system including a substrate stage system with an orientation mechanism in accordance with one or more embodiments of the present invention.

FIG. 2B illustrates a schematic representation of a substrate orientation arrangement for a deposition process in accordance with one or more embodiments of the present invention.

FIG. 3 illustrates a schematic representation of a substrate stage system including a gas shower unit in accordance with one or more embodiments of the present invention.

FIG. 4 illustrates a schematic representation of a cross-sectional view of a substrate seat of a substrate stage system in accordance with one or more embodiments of the present invention.

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

One or more embodiments of the invention relate to an improved substrate stage system for supporting and cooling a substrate during a deposition process. The substrate stage system includes a cooling arrangement that utilizes a confined gas, in contrast with a flowing gas utilized in the prior art, for cooing the substrate. Advantageously, the substrate stage system may substantially reduce consumption of the gas.

The substrate stage system may include a substrate seat made of a thermally conductive material. The substrate stage system may also include a sealing unit coupled with the substrate seat. The sealing unit may be configured to define a boundary of a space between the substrate and the substrate seat. The sealing unit may also be configured to seal the space to inhibit the gas from escaping from the space. Accordingly, the gas may be trapped in the space to serve as a thermal conductor. The substrate seat may include at least a gas channel configured to deliver the gas to the space. The gas channel may include an opening configured for both injecting the gas into the space and withdrawing the gas from the space, in contrast with the gas inlet and outlet required for the flowing gas utilized in the prior art.

Through the gas, the substrate seat may receive heat from the substrate and subsequently dissipate the heat. In one or more embodiments, the substrate seat may also include at least a cooling channel configured to allow a cooling fluid, e.g., water, to flow through the substrate seat for facilitating/accelerating dissipating heat received from the substrate.

The substrate stage system may also include a step unit disposed between the substrate seat and the substrate for maintaining the height of the space. The step unit may be coupled with the substrate seat or may be an integral part of the substrate seat

The substrate stage system may also include a pump coupled with the gas channel and a valve coupled with the gas channel. At least one of the pump and the valve may be configured to maintain a constant pressure for the gas during the deposition process, for a controlled heat dissipation rate.

The substrate stage system may also include a clamp unit. The sealing unit may be compressible, for biasing the substrate against the clamp unit to secure the substrate in place.

The substrate stage system may also include a gas shower unit configured to be disposed between a target material and the substrate during the deposition process. The gas shower unit may include a plurality of distributed gas holes. The distributed gas holes may be configured to provide a process gas in a distributed manner, for substantially homogeneous chemical reaction between the process gas and particles from the target material.

The substrate stage system may also include an orientation mechanism coupled with the substrate seat. The orientation mechanism may be configured to orient the substrate seat such that a surface of the substrate is tilted, i.e., at an angle to an imaginary plane containing a vector of gravity, during the deposition process, for optimizing deposition amid the effect of gravity. The angle may be greater than 0 degree and less than 90 degrees. In one or more embodiments, the angle may be at most 10 degrees.

The orientation mechanism may also be configured to orient the gas shower unit when orienting the substrate seat, such that a distance between the gas shower unit and the substrate may remain constant. The orientation mechanism may also be configured to rotate the substrate around a diameter of the substrate. Accordingly, additional variables and associated complication for optimizing the deposition process may be avoided.

The substrate stage system may also include a shutter coupled with the substrate seat. The shutter may be configured to shield the substrate before and/or after the deposition process, for protecting the substrate from unready or undesirable conditions. The shutter may also be configured to be disposed between the target material and the gas shower unit for preventing the chemical reaction from starting before the deposition process.

The substrate stage system may also include a rotation mechanism configured to rotate the substrate seat (without rotating the shutter and the gas shower unit in one or more embodiments) during the deposition process. Accordingly, the substrate may be rotated during the deposition process for improved homogeneity.

One or more embodiments of the invention relate to a deposition system for performing deposition on a substrate utilizing a target material. The deposition system may include a chamber, within which the deposition may take place. The deposition system may also include a substrate stage system according to one or more embodiments discussed above.

One or more embodiments of the invention relate to a method for performing deposition on a first surface of a substrate utilizing a target material. The method may include supporting the substrate using a substrate seat. The method may also include tilting the substrate seat such that the first surface of the substrate is at an angle to an imaginary plane containing a vector of gravity. The tilting may enable desirable particles to travel toward the substrate substantially orthogonally to the first surface, for optimizing the deposition. The angle may be greater than 0 degree and less than 90 degrees. For example, the angle may be at most 10 degrees. The method may also include maintaining the angle during the deposition. The method may also include rotating the substrate around a center of the substrate during the deposition, for improving homogeneity of the deposition.

The method may also include forming a space between the substrate seat and the substrate. The method may also include filling the space with a gas for transferring heat from the substrate to substrate seat through the gas. The method may also include maintaining a constant pressure for the gas during the deposition, for a controlled heat transfer.

The method may also include providing an opening on the substrate seat for both injecting the gas into the space and withdrawing the gas from the space. Accordingly, manufacturing for the substrate seat may be simplified.

The features and advantages of the present invention may be better understood with reference to the figures and discussions that follow.

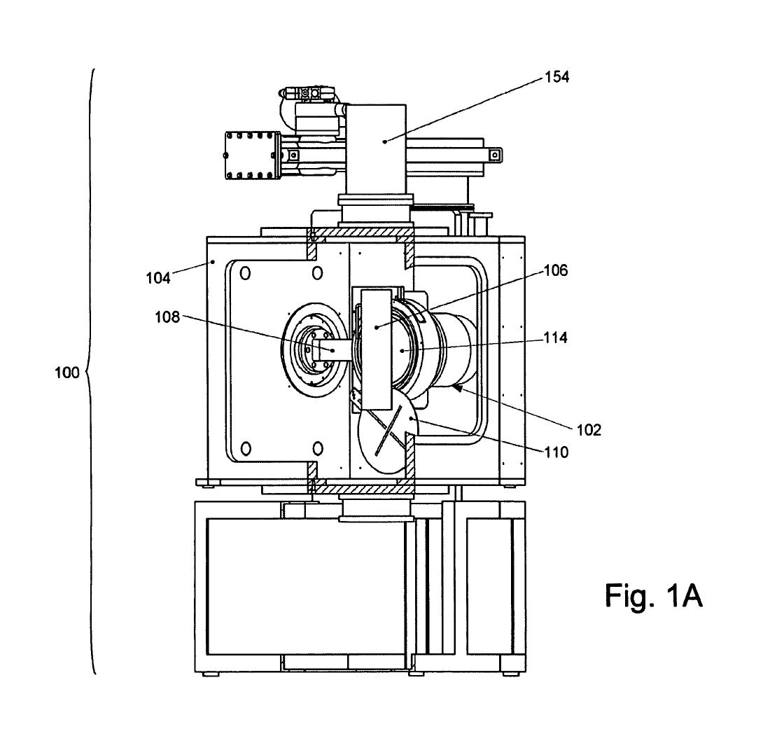

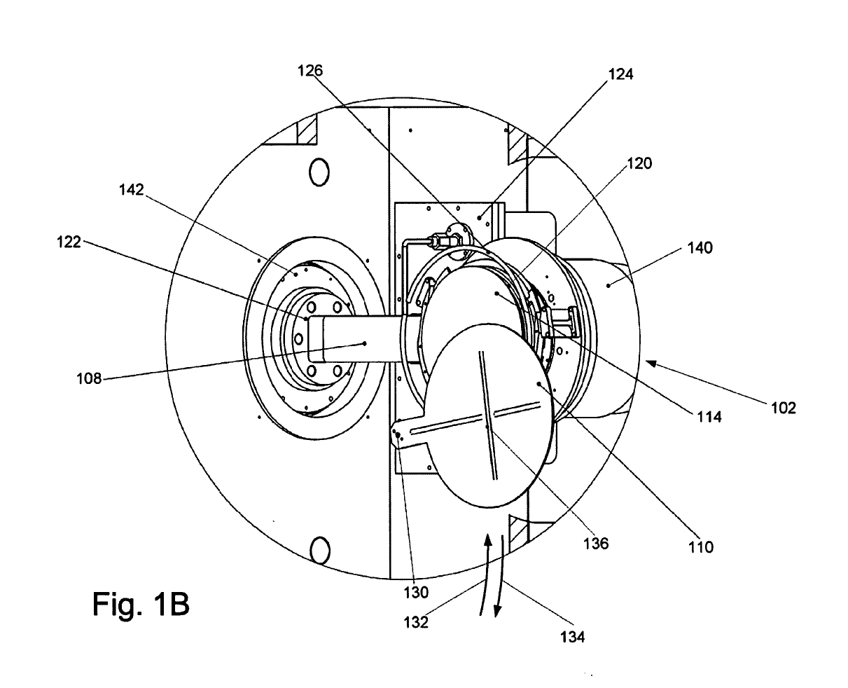

FIG. 1A illustrates a schematic representation of a deposition system 100, including a substrate stage system 102, in accordance with one or more embodiments of the present invention. Deposition system 100 may also include a chamber 104, in which deposition processes may take place. A cut-away view of chamber 104 is shown in the example of FIG. 1A, such that a schematic representation of substrate stage system 102 may be illustrated.

For example, deposition system 100 may be utilized in a deposition process for forming a thin film on a surface of a substrate, such as substrate 114. The deposition process may involve utilizing a target material 106, such as a cylindrical block of aluminum. Deposition system 100 may include a plasma source 154 configured to generate a plasma to sputter target material 106, such that sputtered particles (e.g., atoms) from target material 106 or molecules containing the sputtered atoms may be deposited onto substrate 114. As an example, plasma source 154 may represent a capacitively coupled plasma source, and an end of target material 106 may be coupled with a DC power source (not shown) for facilitating generating the plasma.

Substrate stage system 102 may be configured to support substrate 114 during the deposition process. Substrate stage system 102 may include a shutter 110 configured to shield substrate 114 before and/or after the deposition process. For example, shutter 110 may be configured to shield substrate 114 until sputtered particles from target material 106 (or molecules containing the sputtered atoms) have substantially homogeneously distributed in chamber 104, before allowing deposition to start on substrate 114. Accordingly, the sputtered particles or molecules may be deposited on substrate 114 in a homogeneous manner, such that homogeneity of the thin film formed on substrate 114 may be optimized.

As another example, shutter 110 may be configured to shield substrate 114 once an optimum thickness for the thin film formed on substrate 114 has been achieved. Accordingly, further deposition that may change the thickness and/or homogeneity of the thin film may be prevented.

Deposition system 100 may also include an arm 108 configured to support substrate stage system 102. In one or more embodiments, arm 108 may be considered part of substrate stage system 102.

Further details of substrate stage system 102 are discussed with reference to FIG. 1B.

FIG. 1B illustrates a schematic representation of a partial perspective view of substrate stage system 102 that includes shutter 110 in accordance with one or more embodiments of the present invention. Shutter 110 may be made of a corrosion resistant material, such as stainless steel, for durability consideration and for effective protection for substrate 114. Shutter 110 may include a stiffening structure 136 configured to provide structural stiffness for shutter 110 while minimizing thickness and weight requirements for shutter 110.

Shutter 110 may be configured to rotate around an axis 130 in a covering direction 132 and an uncovering direction 134 to shield and to expose substrate 114, respectively. Alternatively or additionally, shutter 110 may perform shielding and exposing wafer 114 through translational motions.

Shutter 110 may be coupled with a plate 124 through axis 130. Plate 124 may be coupled, e.g., through one or more components of substrate stage system 102, with a substrate seat 120 that is configured to support substrate 114 during the deposition process.

Substrate seat 120 may also be configured to rotate substrate 114 around a center of substrate 114 during the deposition process, for homogeneous deposition. The rotation may be actuated by a rotation mechanism 140 of substrate stage system 102.

Substrate stage system 102 may also include a gas shower unit 126 supported by plate 124 and coupled with substrate seat 120 through one or more components of substrate stage system 102, such as plate 124. Gas shower unit 126 may be configured to be disposed between substrate 114 and target material 106 during the deposition process. Gas shower unit 126 may also be configured to provide a process gas in a homogeneous manner during the deposition process, such that chemical reaction may be facilitated between the process gas and the sputtered particles (from target material 106 illustrated in the example of FIG. 1A). Molecules resulted from the chemical reaction may be deposited on substrate 114.

Gas shower unit 126 may be configured to be shielded by shutter 110 before the deposition process, for preventing the chemical reaction from happening too early, e.g., before there are sufficient sputtered particles in chamber 104 illustrated in the example of FIG. 1A. Shutter 110 may also be configured to shield gas shower unit 126 once the optimum thickness of the thin film has been achieved on substrate 114 or after the deposition process, to prevent further chemical reaction. Advantageously, thickness and homogeneity of the thin film may be optimized.

Substrate stage system 102 may also include an orientation mechanism 142 configured to adjust the orientation of wafer 114 with respect to target material 106 (illustrated in the example of FIG. 1A) for optimum deposition. Orientation mechanism 142 may be coupled with substrate seat 120 through one or more components, such as arm 108 and feature mount 122.

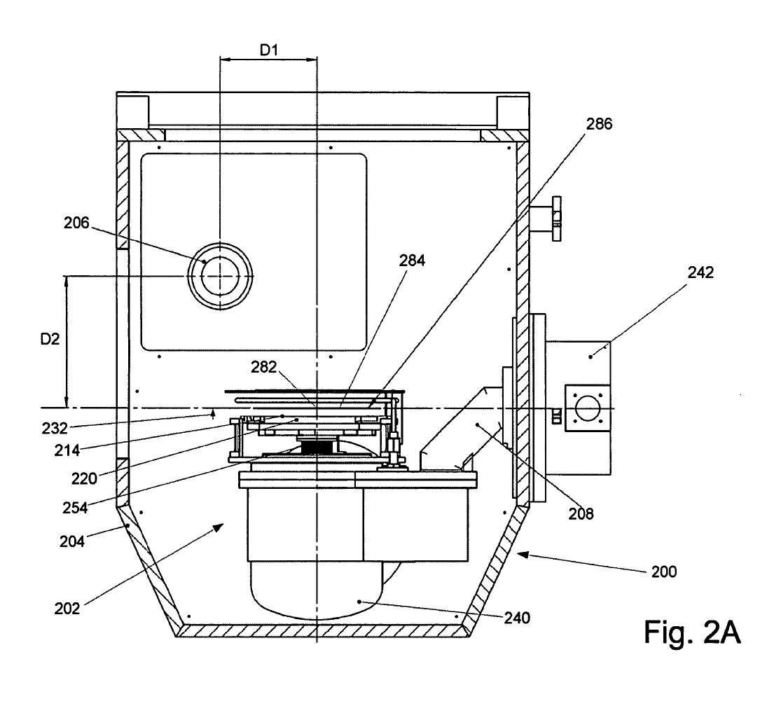

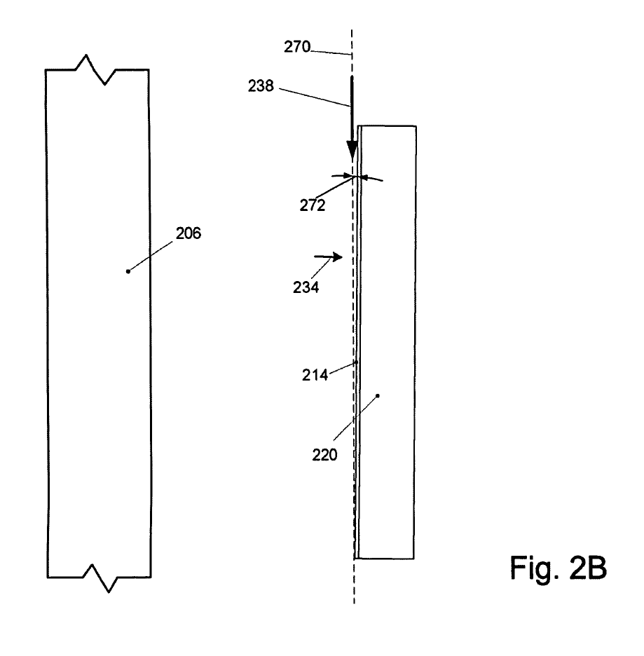

FIG. 2A illustrates a schematic representation of a partial top cut-away view of a deposition system 200 in accordance with one or more embodiments of the present invention. Deposition system 200 may be utilized for performing deposition, for example, on a substrate 214 utilizing a target material 206. Deposition system 200 may include a chamber 204 to contain sputtered particles from target material 206. Deposition system 200 may also include a substrate stage system 202 configured to support substrate 214 during the deposition process. One or more components of substrate stage system 202 may be disposed inside chamber 204.

Substrate stage system 202 may include a substrate seat 220 for securing substrate 214 in place during the deposition process. Substrate stage system 202 may also include a positioning mechanism 254 coupled with substrate seat 220 and configured to move substrate seat 220 in a direction 232 to place substrate 214 at position 286 for the deposition.

Substrate stage system 202 may also include an orientation mechanism 242, configured to tilt substrate seat 220, such that substrate 214 may have an optimal orientation during the deposition. Orientation mechanism 242 may be coupled with substrate seat 220 through one or more components, such as arm 208. Orientation mechanism 242 may be configured to orient/rotate substrate 214 around a diameter 284 of substrate 214 when substrate 214 is in position 286. Accordingly, a distance D2 between target material 206 and a central line of substrate 214, represented by diameter 284, may remain constant for various orientations of substrate 214. Given that distance D2 is maintained constant, the number of variables involved in optimizing the deposition process might be minimized. Therefore, optimizing the deposition process may be simplified.

Substrate stage system 202 may also include a rotation mechanism 240, configured to rotate substrate 214 around the center 282 of substrate 214 when substrate 214 is in position 286 during the deposition. With the rotation, homogeneity of the deposition may be improved. A distance D1 between target material 206 and center 202 may be maintained constant during the deposition process. With distance D1 being maintained constant, the number of variables involved in optimizing the deposition process may also be minimized, and the optimization may be simplified.

FIG. 2B illustrates an orientation arrangement for substrate seat 220 and substrate 214 in accordance with one or more embodiments of the present invention. Orientation mechanism 242 (illustrated in the example of FIG. 2A) may orient/tilt substrate seat 220 such that substrate 214 is at an angle 272 with respect to an imaginary plane 270 containing a gravity vector 238. Orienting/tilting substrate seat 220 (and/or substrate 214) may represent a process step in a deposition process in one or more embodiments of the invention.

Angle 272 may be greater than zero degree such that substrate 214 is not in line with gravity vector 238. Angle 272 may be less than 90 degrees, such that the surface of substrate 214 for the deposition is not perpendicular to gravity vector 238. Angle 272 may be configured such that sputtered particles from a target material 206 may approach substrate 214 in a direction 234 that is substantially orthogonal to the surface of substrate 214 for the deposition. Angle 272 may be optimized With gravity and the dynamics of the sputtered particles (and/or molecules containing the sputtered particles) taken into consideration. For example, angle 272 may be at most 10 degrees. As another example, angle 272 may be approximately 10 degrees.

With sputtered particles (and/or molecules containing the sputtered particles) approaching substrate 214 in a direction that is substantially orthogonal to the deposition surface, the efficiency for the deposition process may be substantially improved.

Given that angle 272 is substantially small, the majority of contaminants, such as flakes from target material 206, which generally weigh more than the particles or molecules for deposition, may be unlikely to attach to the deposition surface of substrate 214. Advantageously, the yield associated with the deposition process may be substantially improved.

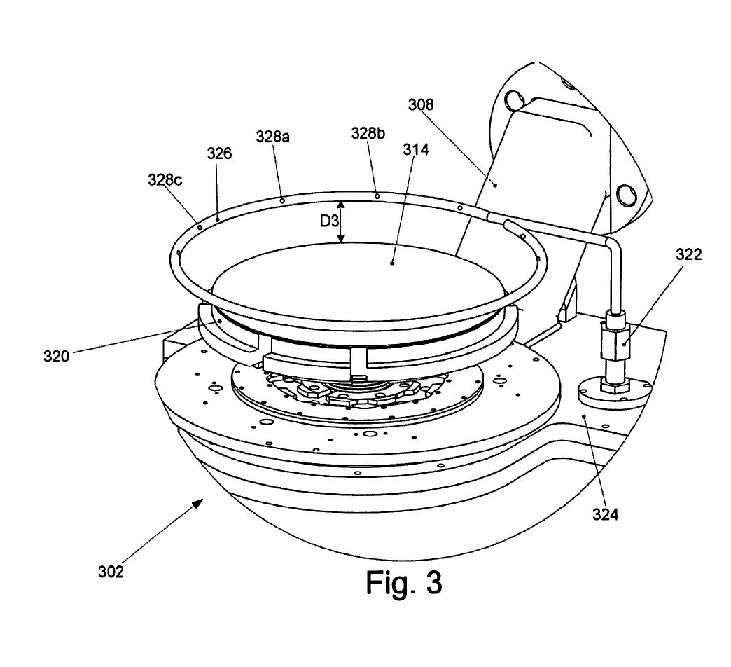

FIG. 3 illustrates a schematic representation of a partial perspective view of a substrate stage system 302 in accordance with one or more embodiments of the present invention. Substrate stage system 302 may include a substrate seat 320 configured to support a substrate, such as substrate 314.

Substrate stage system 302 may also include a gas shower unit 326, configured to be disposed between substrate 314 (supported by substrate seat 320) and a target material (for example, similar to target material 106 illustrated in the example of FIG. 1A) during a deposition process. Gas shower unit 326 may be made of a corrosion resistant material, such as stainless steel, for durability and consistent performance. Gas shower unit 326 may include a gas inlet 322 for receiving gas supply and may be coupled with a plate 324 through gas inlet 322. Plate 324 may be configured to support and stabilize gas shower unit 326 during the deposition process.

Gas shower unit 326 may include a plurality of gas holes, such as gas holes 328a-c, configured to provide a process gas, such as oxygen, for facilitating chemical reaction between the process gas and sputtered particles from the target material during the deposition process. The gas holes may be distributed along at least a portion of gas shower unit 326 such that the chemical reaction may be substantially homogeneous over the surface of substrate 314 for the deposition. The shape of the portion of gas shower unit 326 may be configured to be similar to the outline of substrate 314, for uniform supply of the process gas over substrate 314. For example, if substrate 314 represents a circular wafer, gas shower unit 326 may have a circular ring shape. Advantageously, homogeneity of the thin film formed on substrate 314 may be substantially improved.

Substrate stage system 326 may also include an orientation mechanism (not shown) similar to orientation mechanism 242 illustrated in the example of FIG. 2A. Substrate seat 320 and gas shower unit 326 may be coupled with the orientation mechanism through one or more components of substrate stage system 302, such as plate 324 and/or arm 308. The orientation mechanism may be configured to substrate seat 320, and therefore orient substrate 314, with respect to the target material, such that the deposition may be optimized, e.g., in efficiency, yield, etc. The orientation mechanism may be configured to also orient gas shower unit 326 when orienting substrate 314, such that a distance D3 between substrate 314 and gas shower unit 326 may remain constant. With D3 being maintained constant, the number of variables involved in optimizing the deposition process may be minimized, and optimizing the deposition process may therefore be simplified.

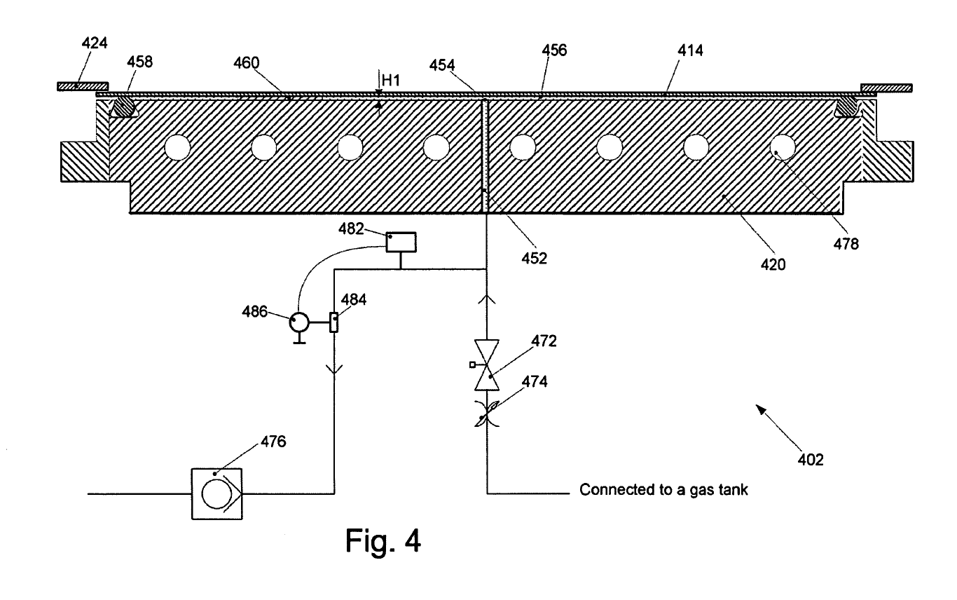

FIG. 4 illustrates a schematic representation of a partial cross-sectional view of a substrate seat 420 of a substrate stage system 402 in a deposition system (for example, similar to deposition system 100 illustrated in the example of FIG. 1) in accordance with one or more embodiments of the present invention. Substrate seat 420 may be configured for supporting and cooling a substrate, such as substrate 414, during a deposition process.

Substrate seat 420 may be made of a thermally conductive material, such as aluminum, for facilitating the cooling. Substrate stage system may also include a sealing unit 458 coupled with substrate seat 420 and configured to define a boundary of a space 456 formed between substrate seat 420 and substrate 414. The shape of sealing unit 458 may be similar to the outline of substrate 414. For example, if substrate 414 represents a circular wafer, sealing unit 458 may have a circular ring shape.

Substrate seat 420 may include a gas channel 452 configured to deliver a gas, such as helium, to fill space 456. Gas channel 452 may include an opening 454 for both injecting the gas into space 456 and withdrawing the gas from space 456. Accordingly, manufacturing of substrate seat 420 may be simplified. Sealing unit 458 may seal space 456, and therefore the gas may be inhibited from escaping from space 456. Filling space 456 with the gas and sealing space 456 may represent process steps for the deposition process.

Substrate stage system 402 may also include a mass flow control 474 and a valve 472 for controlling the input of the gas into space 456. Substrate stage system 402 may also include a pump 476, configured to withdraw the gas from space 456. Substrate stage system 402 may also include a capacitance manometer 482 for measuring the flow rate of the gas withdrawn from space 456. Substrate stage system 402 may also include a controller 486 (coupled with capacitance manometer 482) for controlling the flow rate of the gas withdrawn from space 456, for example, by expanding or contracting an orifice 484 disposed in the path of the withdrawn gas, thereby controlling the gas pressure in space 456. At least one of valve 472, mass flow control 474, capacitance manometer 482, controller 486, orifice 484, and pump 476, may be configured to maintain a constant pressure for the gas in space 456 during the deposition process.

During the deposition process, the gas may serve as a thermal conductor between substrate 414 and substrate seat 420 for thermally coupling substrate 414 and substrate seat 420. Accordingly, substrate seat 420 may receive heat from substrate 414 through the gas and may subsequently dissipate the heat. Heat transfer from substrate 414 to substrate seat 420 may represent a process step in the deposition process.

During the deposition process, the amount of the gas that is utilized may be substantially represented by the volume of space 456 (and gas channel 452 and other gas conduits). Since the gas is sealed by sealing unit 458 without substantially flowing out of space 456 during the deposition process, the amount of the gas utilized during the deposition process may be minimized, compared with the prior art arrangement that involves a continuous flow of a cooling gas. Advantageously, cooling cost associated with the deposition process may be reduced.

Substrate seat 420 may also include a cooling channel 478 configured to allow a cooling fluid, such as water or water-alcohol mixture, to flow through substrates 420. The cooling fluid may facilitate and/or accelerate dissipation of the heat.

Substrate stage system 402 may also include a step unit 460 configured to contact substrate 414. Step unit 460 may also be configured to maintain a height H1 for space 456 between substrate 414 and substrate seat 420. Step unit 460 may be attached to substrate seat 420 or may be an integral part of substrate seat 420.

Substrate stage system 402 may also include a clamp unit 424 configured to secure substrate 414 in place. In one or more embodiments, sealing unit 458 may be made of a compressible material and may be configured to bias substrate 414 against clamp unit 424 during the deposition process. Accordingly, substrate 414 may remain stable during the deposition process, and the deposition process may be optimized without considering shifting of substrate 414.

As can be appreciated from the foregoing, embodiments of the present invention may eliminate the need for a continuous flow of cooling gas during deposition processes. Advantageously, the cost associated with cooling for deposition processes may be substantially reduced.

Embodiments of the invention may also protect substrates when the environment surrounding the substrates is not ready or is not suitable for deposition. Accordingly, homogeneity of thin films formed on the substrates may be optimized. Advantageously, the yield associated with deposition processes may be optimized.

Embodiments of the invention may also enable sputtered particles and molecules for deposition to approach surface of substrates in directions that are substantially orthogonal to the surfaces. Advantageously, efficiency for deposition processes may be substantially improved.

Embodiments of the present invention may also provide homogeneous chemical reactions between process gases and sputtered particles from target materials over substrates during deposition processes. Advantageously, homogeneity of thin films formed on the substrates may be optimized.

While this invention has been described in terms of several embodiments, there are alterations, permutations, and equivalents, which fall within the scope of this invention. It should also be noted that there are many alternative ways of implementing the methods and apparatuses of the present invention. Furthermore, embodiments of the present invention may find utility in other applications. The abstract section is provided herein for convenience and, due to word count limitation, is accordingly written for reading convenience and should not be employed to limit the scope of the claims. It is therefore intended that the following appended claims be interpreted as including all such alterations, permutations, and equivalents as fall within the true spirit and scope of the present invention.

What is claimed is:

1. A substrate stage system for supporting and cooling a substrate during a deposition process that involves utilizing a target material, the substrate stage comprising:
a substrate seat made of a thermally conductive material; and
a sealing unit coupled with the substrate seat, the sealing unit configured to define a boundary of a space between the substrate and the substrate seat,
wherein the substrate seat includes at least a gas channel configured to deliver a gas to the space,
the sealing unit is further configured to seal the space to inhibit the gas from escaping from the space, and
the substrate seat is configured to receive heat from the substrate through the gas and is configured to dissipate the heat.

2. The substrate stage system of claim 1 further comprising a step unit coupled with the substrate seat, the step unit configured to contact the substrate and to maintain a height of the space.

3. The substrate stage system of claim 1 wherein the substrate seat further includes at least a cooling channel configured to allow a cooling fluid to flow through the substrate seat for dissipating the heat received from the substrate.

4. The substrate stage system of claim 1 further comprising:
a pump coupled with the gas channel for withdrawn at least a portion of the gas from the space;
a valve coupled with the gas channel for controlling input of the gas into the space;
a controller coupled with the gas channel for controlling a flow rate of the at least a portion of the gas withdrawn from the space, thereby controlling a gas pressure in the space,
wherein at least one of the pump, the valve, and the controller is configured to maintain a constant pressure for the gas during the deposition process.

5. The substrate stage system of claim 1 further comprising a clamp unit, wherein the sealing unit is compressible and is configured to bias the substrate against the clamp unit.

6. The substrate stage system of claim 1 further comprising an orientation mechanism coupled with the substrate seat and configured to orient the substrate seat such that a surface of the substrate is at an angle to an imaginary plane containing a vector of gravity during the deposition process, the angle being greater than 0 degree and being less than 90 degrees.

7. The substrate stage system of claim 6 wherein the angle is at most 10 degrees.

8. The substrate stage of claim 1 further comprising an orientation mechanism couple with the substrate stage and configured to rotate the substrate around a diameter of the substrate.

9. The substrate stage system of claim 1 further comprising a gas shower unit configured to be disposed between the target material and the substrate during the deposition process, the gas shower unit including a plurality of gas holes configured to provide a process gas for chemical reaction between the process gas and particles from the target material during the deposition process.

10. The substrate stage system of claim 9 further comprising an orientation mechanism coupled with the substrate seat and configured to orient the substrate seat and the gas shower unit such that a surface of the substrate is at an angle to an imaginary plane containing a vector of gravity during the deposition process and that a distance between the substrate and the gas shower unit remains constant, the angle being greater than 0 degree and being less than 90 degrees.

11. The substrate stage system of claim 1 further comprising a shutter coupled with the substrate seat and configured to shield the substrate before the deposition process.

12. The substrate stage system of claim 1 further comprising a shutter configured to be disposed between the target material and the gas shower unit for preventing the chemical reaction from starting before the deposition process.

13. The substrate stage system of claim 1 further comprising a rotation mechanism configured to rotate the substrate seat.

14. The substrate stage system of claim 1 wherein the gas channel includes at least an opening configured for injecting the gas into the space and for withdrawing the gas from the space.

15. A deposition system for performing deposition on a substrate utilizing a target material, the deposition system comprising:
a chamber;
a substrate seat made of a thermally conductive material and disposed inside the chamber, the substrate seat including at least a step unit configured to contact the substrate and to maintain a height of a space between the substrate and the substrate seat, the substrate seat further including at least a gas channel configured to deliver a gas to the space;
a sealing unit coupled with the substrate seat, the sealing unit configured to seal the space to prevent the gas from escaping into the chamber;
a pump coupled with the gas channel; and
a valve coupled with the gas channel,
wherein at least one of the pump and the valve is configured to maintain a constant pressure for the gas during the deposition, and
the substrate seat is configured to receive heat from the substrate through the gas and is configured to dissipate the heat.

16. The deposition system of claim 15 further comprising a shutter coupled with the substrate seat and configured to shield the substrate after the deposition.

17. The deposition system of claim 15 further comprising:
a gas shower unit configured to be disposed between the target material and the substrate during the deposition, the gas shower unit including a plurality of gas holes configured to provide a process gas for chemical reaction between the process gas and particles from the target material during the deposition; and
an orientation mechanism coupled with the substrate seat and configured to orient the substrate seat and the gas shower unit such that a surface of the substrate is at an angle to an imaginary plane containing a vector of gravity during the deposition and that a distance between the substrate and the gas shower unit remains constant, the angle being greater than 0 degree and being less than 90 degrees.

18. A method for performing deposition on a first surface of a substrate utilizing a target material, the method comprising:
supporting the substrate using a substrate seat;
tilting the substrate seat such that the first surface of the substrate is at an angle to an imaginary plane containing a vector of gravity, the angle being greater than 0 degree and being less than 90 degrees; and
maintaining the angle during the deposition.

19. The method of claim 18 wherein the angle is at most 10 degrees.

20. The method of claim 18 further comprising:
forming a space between the substrate seat and the substrate,
filling the space with a gas for transferring heat from the substrate to substrate seat through the gas;
preventing the gas from escaping; and
maintaining a constant pressure for the gas during the deposition.

21. The method of claim 20 further comprising:
providing an opening on the substrate seat for injecting the gas into the space and for withdrawing the gas from the space; and
rotating the substrate around a center of the substrate during the deposition.
